(19) United States
(12) Patent Application Publication
(10) Pub. No.: US 2026/0255975 A1
(43) Pub. Date: Aug. 27, 2026

(54) SEMICONDUCTOR DEVICE

(71) Applicant: Kioxia Corporation, Tokyo (JP)

(72) Inventors: Gen MORIKAWA, Chigasaki (JP); Hiroyuki MAEDA, Kawasaki (JP)

(73) Assignee: Kioxia Corporation, Tokyo (JP)

(21) Appl. No.: 19/302,730

(22) Filed: Aug. 18, 2025

(30) Foreign Application Priority Data
Feb. 27, 2025 (JP) 2025-030387

(51) Int. Cl. H01L 23/00; H01L 23/58; H01L 25/065; H01L 25/18; H10B 80/00

(52) U.S. Cl. CPC H10W 42/121; H10B 80/00; H10W 42/00; H10W 90/00; H10W 72/5366; H10W 90/754; H10W 90/792

(57) ABSTRACT

In general, according to one embodiment, a semiconductor device includes: a substrate having a major surface, the substrate including a first region, and a second region provided in such a manner as to surround an outer periphery of the first region as viewed in a first direction, the first direction perpendicular to the major surface; a semiconductor circuit provided in the first region on the substrate; a plurality of first conductive pillars provided in the second region on the substrate, spaced apart from each other and arranged in such a manner as to surround the first region, the first conductive pillars extending in the first direction, being electrically insulated from each other and from the semiconductor circuit; and a passivation film provided in the first region and overlapping the semiconductor circuit in the first direction, wherein a part of the first conductive pillars is exposed from the passivation film.

### CROSS-REFERENCE TO RELATED APPLICATION

This application is based upon and claims the benefit of priority from prior Japanese Patent Application No. 2025-030387, filed Feb. 27, 2025, the entire contents of which are incorporated herein by reference.

### FIELD

Embodiments described herein relate generally to a semiconductor device.

### BACKGROUND

As a semiconductor device, there is known a semiconductor memory device including a NAND flash memory capable of storing data in a nonvolatile manner. In the NAND flash memory, there is a case where a three-dimensional memory configuration is adopted for higher integration density and greater capacity.

### BRIEF DESCRIPTION OF THE DRAWINGS

FIG. 1 is a block diagram illustrating an example of a configuration of a memory system according to an embodiment.

FIG. 2 is a cross-sectional view illustrating an example of a cross-sectional configuration of the memory system according to the embodiment.

FIG. 3 is a perspective view illustrating an example of an external appearance of a semiconductor memory device according to the embodiment.

FIG. 4 is a circuit diagram illustrating an example of a circuit configuration of a memory cell array included in the semiconductor memory device according to the embodiment.

FIG. 5 is a cross-sectional view illustrating an example of a cross-sectional configuration of the memory cell array in the semiconductor memory device according to the embodiment.

FIG. 6 is a cross-sectional view taken along line VI-VI in FIG. 5, FIG. 6 illustrating an example of a cross-sectional configuration of a memory pillar included in the semiconductor memory device according to the embodiment.

FIG. 7 is a plan view illustrating an example of a planar layout of the semiconductor memory device according to the embodiment.

FIG. 8 is a cross-sectional view illustrating an example of a cross-sectional configuration of the semiconductor memory device according to the embodiment.

FIG. 9 is a plan view illustrating an example of a connection between the semiconductor memory device according to the embodiment and a wiring board.

FIG. 10 is a cross-sectional view illustrating an example of a connection between the semiconductor memory device according to the embodiment and the wiring board.

FIG. 11 is a plan view illustrating an example of a planar layout in a case of executing characteristic evaluation in the semiconductor memory device according to the embodiment.

FIG. 12 is a plan view illustrating an example of a planar layout of a semiconductor memory device according to a first modification of the embodiment.

FIG. 13 is a plan view illustrating an example of a planar layout of a semiconductor memory device according to a second modification of the embodiment.

FIG. 14 is a plan view illustrating an example of a planar layout of a semiconductor memory device according to a third modification of the embodiment.

### DETAILED DESCRIPTION

In general, according to one embodiment, a semiconductor device includes: a substrate having a major surface, the substrate including a first region, and a second region provided in such a manner as to surround an outer periphery of the first region as viewed in a first direction, the first direction being a direction perpendicular to the major surface; a semiconductor circuit provided in the first region on the substrate; a plurality of first conductive pillars provided in the second region on the substrate, spaced apart from each other and arranged in such a manner as to surround the first region, the first conductive pillars extending in the first direction, being electrically insulated from each other and being insulated from the semiconductor circuit; and a passivation film provided in the first region and overlapping the semiconductor circuit in the first direction, the passivation film being provided on an opposite side to the substrate in the first direction with respect to the semiconductor circuit and the first conductive pillars, wherein at least a part of the first conductive pillars is exposed from the passivation film.

Hereinafter, an embodiment is described with reference to the accompanying drawings. The drawings are schematic ones, and the dimensions and ratios in the drawings are not necessarily identical to real ones. In the description below, structural elements having substantially identical functions and structures are denoted by an identical reference sign. In a case where elements having similar structures are particularly distinguished, there is a case in which mutually different characters or numerals are added to the end of an identical reference sign.

In the description below, an expression that a certain first element is “coupled” to another second element includes a mode in which the first element is indirectly coupled to the second element via an intermediate element that is always or selectively rendered conductive, or is directly coupled to the second element without via the intermediate element.

Hereinafter, a semiconductor memory device having a three-dimensional memory configuration is described as an example of a semiconductor device according to an embodiment.
1. Configuration
1.1. Memory System

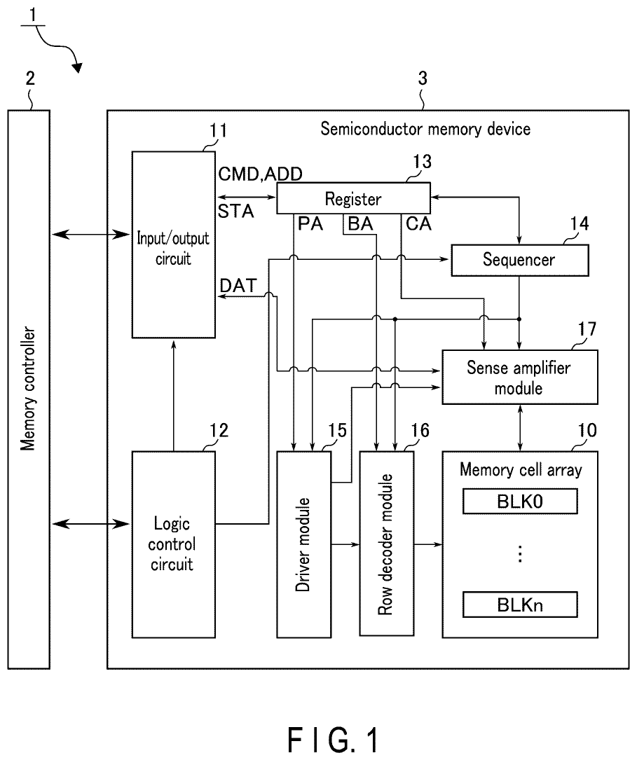

A semiconductor memory device according to an embodiment is described. FIG. 1 is a block diagram illustrating an example of a configuration of a memory system according to the embodiment. A memory system 1 is a memory device configured to be coupled to an external host device (not illustrated). The memory system 1 is, for example, a memory card such as an SD™ card, a UFS (Universal Flash Storage), or an SSD (Solid State Drive). The memory system 1 includes a memory controller 2 and a semiconductor memory device 3.

The memory controller 2 is composed of, for example, an integrated circuit such as an SoC (System on a Chip). The memory controller 2 controls the semiconductor memory device 3, based on a request from the external host device. Specifically, the memory controller 2 writes data, write of which is requested from the external host device, into the semiconductor memory device 3. In addition, the memory controller 2 reads out data, read of which is requested from the external host device, from the semiconductor memory device 3, and outputs the read-out data to the external host device.

The semiconductor memory device 3 is, for example, a NAND flash memory capable of storing data in a nonvolatile manner.

The communication between the memory controller 2 and the semiconductor memory device 3 supports, for example, an SDR (Single Data Rate) interface, a toggle DDR (Double Data Rate) interface, or an ONFI (Open NAND Flash Interface).

### 1.2. Semiconductor Memory Device

Next, referring to the block diagram of FIG. 1, an internal configuration of the semiconductor memory device 3 according to the embodiment is described. The semiconductor memory device 3 includes, for example, a memory cell array 10, an input/output circuit 11, a logic control circuit 12, a register 13, a sequencer 14, a driver module 15, a row decoder module 16, and a sense amplifier module 17.

The memory cell array 10 is a set including a group of memory cell transistors, and structural elements coupled to the memory cell transistors. The memory cell array 10 includes a plurality of blocks BLK0 to BLKn (n is an integer of 1 or more). The block BLK is a set of memory cell transistors capable of storing data in a nonvolatile manner. The block BLK is used as, for example, an erase unit at a time of erasing data stored in the memory cell transistors. In addition, a plurality of bit lines and a plurality of word lines are provided in the memory cell array 10. Each memory cell transistor is associated with, for example, a combination of one bit line and one word line. A detailed configuration of the memory cell array 10 will be described later.

The input/output circuit 11 is an interface circuit that controls transmission/reception of input/output signals to/from the memory controller 2. The input/output signals include, for example, data DAT, a command CMD, address information ADD, and status information STA. The input/output circuit 11 inputs and outputs the data DAT between the sense amplifier module 17 and the memory controller 2. The input/output circuit 11 outputs the command CMD and address information ADD, which are transferred from the memory controller 2, to the register 13. The input/output circuit 11 outputs the status information STA, which is transferred from the register 13, to the memory controller 2.

The logic control circuit 12 receives a control signal that is input from the memory controller 2. Based on the control signal, the logic control circuit 12 controls the input/output circuit 11 and the sequencer 14. For example, the logic control circuit 12 notifies the input/output circuit 11 that the input/output signal received by the input/output circuit 11 is the command CMD, address information ADD, or the like. The logic control circuit 12 orders the input/output circuit 11 to input or output the input/output signal. The logic control circuit 12 controls the sequencer 14, and enables the semiconductor memory device 3. In addition, the logic control circuit 12 outputs to the memory controller 2 a signal indicating whether the semiconductor memory device 3 is in a ready state or a busy state.

The register 13 temporarily stores the command CMD, address information ADD and status information STA. The command CMD includes, for example, instructions for causing the sequencer 14 to execute a read operation, a write operation, and an erase operation. The address information ADD includes, for example, a block address BA, a page address PA, and a column address CA. For example, the block address BA, page address PA, and column address CA are used for selecting a block BLK, a word line and a bit line, respectively. The status information STA is updated based on the control of the sequencer 14, and is transferred to the input/output circuit 11.

The sequencer 14 controls an overall operation of the semiconductor memory device 3. For example, based on the command CMD stored in the register 13, the sequencer 14 controls the driver module 15, the row decoder module 16 and the sense amplifier module 17, and executes the read operation, write operation and erase operation.

The driver module 15 generates voltages of different magnitudes, which are used in the read operation, write operation and erase operation. The driver module 15 supplies the generated voltages to the row decoder module 16 and the sense amplifier module 17. In addition, the driver module 15 applies the generated voltage, for example, to a signal line corresponding to a word line that is selected based on the page address PA stored in the register 13.

The row decoder module 16 selects, for example, based on the block address BA stored in the register 13, one corresponding block BLK in the memory cell array 10. The row decoder module 16 transfers, for example, a voltage of a signal line, which is applied by the driver module 15, to a selected word line in a selected block BLK.

The sense amplifier module 17 includes a sense amplifier capable of determining data, based on the voltage of an associated bit line, and a latch circuit that temporarily stores data. In the write operation, the sense amplifier module 17 applies a desired voltage to each bit line, in accordance with write data DAT received from the input/output circuit 11. In addition, in the read operation, the sense amplifier module 17 determines data stored in the memory cell transistor, based on the magnitude of the voltage of the bit line. Thereafter, the sense amplifier module 17 transfers the result of the determination to the input/output circuit 11 as read data DAT.

### 1.3. Configuration of Memory System

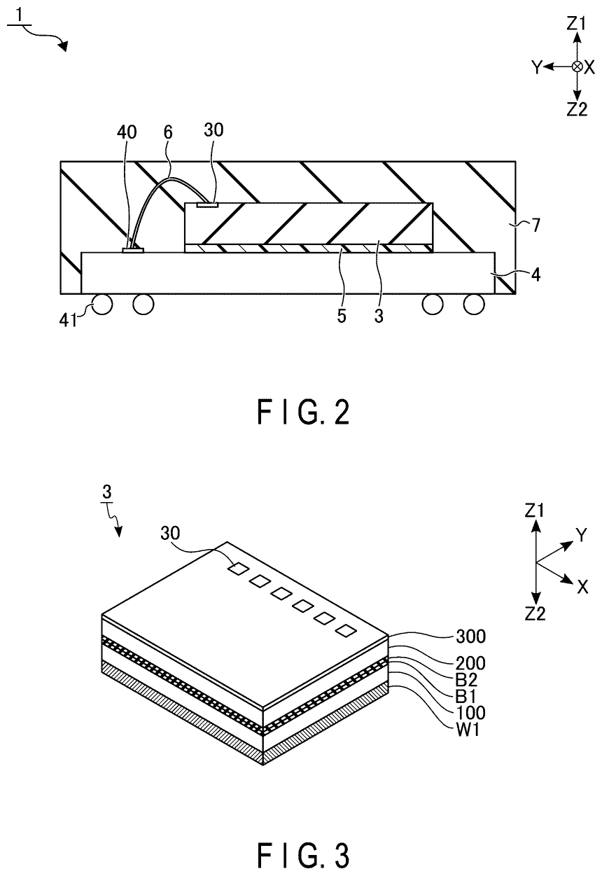

FIG. 2 is a cross-sectional view illustrating an example of a cross-sectional configuration of the memory system according to the embodiment. As illustrated in FIG. 2, the memory system 1 according to the embodiment further includes a wiring board 4, an adhesive layer 5, an interconnect 6, and a resin layer 7. FIG. 2 illustrates a scene in which the semiconductor memory device 3 is provided on the wiring board 4.

In the description below, a plane in which the wiring board 4 extends is defined as an XY plane. A direction in which the semiconductor memory device 3 is provided, as viewed from a direction perpendicular to a major surface of the wiring board 4, is defined as a Z1 direction or an upward direction. A direction opposite to the Z1 direction or upward direction is defined as a Z2 direction or a downward direction. In addition, in a case where the Z1 direction and the Z2 direction are not distinguished, these directions are simply referred to as a Z direction. The Z direction is substantially perpendicular to the wiring board 4.

The semiconductor memory device 3 includes a pad 30. Although FIG. 2 illustrates only one pad 30, a plurality of pads 30 are actually provided. The semiconductor memory device 3 is coupled to the memory controller 2, an external power supply, and the like via the pads 30.

The wiring board 4 is, for example, a printed board or an interposer, which includes a glass epoxy resin. The semiconductor memory device 3 is provided on an upper surface of the wiring board 4 via the adhesive layer 5. The adhesive layer 5 is a paste-like or film-like resin, and includes, for example, an NCP (Non-Conductive Paste) or a DAF (Die Attach Film).

The wiring board 4 includes a pad 40 and electrodes 41. The pad 40 is provided on the upper surface of the wiring board 4. The pad 40 is coupled to a circuit provided in the inside of the wiring board 4, and functions as a terminal of the wiring board 4. The pad 40 is coupled to the semiconductor memory device 3 provided on the wiring board 4, the memory controller 2 (not illustrated), and the like. Although not illustrated, a plurality of pads 40 are provided. The electrodes 41 are, for example, bump electrodes. The electrodes 41 are provided on a lower surface of the wiring board 4. The electrodes 41 are coupled to interconnects provided in the inside of the wiring board 4, and function as terminals of the wiring board 4. The electrodes 41 are coupled to a host device, a power supply and the like, which are not illustrated and are provided on the outside of the memory system 1.

The interconnect 6 is a bonding wire and includes, for example, copper (Cu), gold (Au) or silver (Ag). The interconnect 6 couples the pad 30 of the semiconductor memory device 3 and the pad 40 of the wiring board 4. Although not illustrated, a plurality of interconnects 6 are provided in accordance with the number of pads 30.

The resin layer 7 seals and protects the semiconductor memory device 3 and the interconnect 6 on the wiring board 4. The resin layer 7 includes, for example, a thermosetting resin such as epoxy resin or acrylic resin.

In the example illustrated in FIG. 2, only one semiconductor memory device 3 is provided on the wiring board 4, but a plurality of semiconductor memory devices 3 may be provided. In this case, one semiconductor memory device 3 may be provided on another semiconductor memory device 3 in an overlapping manner. In addition, although not illustrated in FIG. 2, the memory controller 2 is also provided on the wiring board 4. The memory controller 2 and the semiconductor memory device 3 are coupled to each other via an interconnect provided in the inside of the wiring board 4.

### 1.4. External Appearance of Semiconductor Memory Device

The semiconductor memory device 3 according to the embodiment is formed such that two semiconductor substrates, on each of which a semiconductor structure is formed, are bonded, and the bonded semiconductor substrates are separated for each chip. Specifically, the semiconductor memory device 3 according to the embodiment includes a structure that is formed by bonding semiconductor substrates W1 and W2. Each of the semiconductor substrates W1 and W2 is a silicon substrate. Hereinafter, a case is described in which the semiconductor substrate W2 is removed in a manufacturing process of the semiconductor memory device 3. Note that, depending on the configuration of the semiconductor memory device 3, a part of the semiconductor substrate W2 may be left after the bonding.

FIG. 3 is a perspective view illustrating an example of an external appearance of the semiconductor memory device according to the embodiment. In FIG. 3, in order to enhance the visibility of the drawing, hatching is added, but the hatching is not necessarily related to the materials or characteristics of structural elements to which the hatching is added. As illustrated in FIG. 3, the semiconductor memory device 3 includes, for example, a configuration in which the semiconductor substrate W1, a control circuit layer 100, a joint layer B1, a joint layer B2, a memory layer 200, and an interconnect layer 300 are stacked in the named order.

The control circuit layer 100 includes a control circuit that is formed by utilizing the semiconductor substrate W1. The semiconductor substrate W1 includes an impurity diffusion region or the like in accordance with the design of the control circuit. The control circuit layer 100 includes, for example, the input/output circuit 11, the logic control circuit 12, the register 13, the sequencer 14, the driver module 15, the row decoder module 16, and the sense amplifier module 17.

The joint layer B1 is provided on the control circuit layer 100. The joint layer B1 is formed by utilizing the semiconductor substrate W1. The joint layer B1 includes a plurality of joint pads that are electrically coupled to the control circuit provided in the control circuit layer 100 and that form a part of the semiconductor circuit.

The joint layer B2 is provided on the joint layer B1. The joint layer B2 is formed by utilizing the semiconductor substrate W2 (not illustrated). The joint layer B2 includes a plurality of joint pads that are electrically coupled to the memory cell array 10 provided in the memory layer 200 and that form a part of the semiconductor circuit. The joint pads included in the joint layer B2 are coupled to the joint pads included in the joint layer B1. A boundary surface between the joint layers B1 and B2 corresponds to a boundary between a layer formed by utilizing the semiconductor substrate W1 and a layer formed by utilizing the semiconductor substrate W2, that is, a joint surface.

The memory layer 200 is provided on the joint layer B2. The memory layer 200 is formed by utilizing the semiconductor substrate W2 (not illustrated). The memory layer 200 includes, for example, the memory cell array 10.

The interconnect layer 300 is provided on the memory layer 200. The interconnect layer 300 is formed in a part from which the semiconductor substrate W2 is removed, after the semiconductor substrates W1 and W2 are bonded. The interconnect layer 300 includes, for example, interconnects coupled to the semiconductor circuit provided in the memory layer 200, and a plurality of pads 30.

Although the semiconductor memory device 3 is illustrated as having a parallelepipedic shape, the shape of the semiconductor memory device 3 is not limited to the parallelepipedic shape. For example, the semiconductor memory device 3 may have such a structure that a part near a dicing line is recessed relative to the other part.

### 1.5. Circuit Configuration of Memory Cell Array

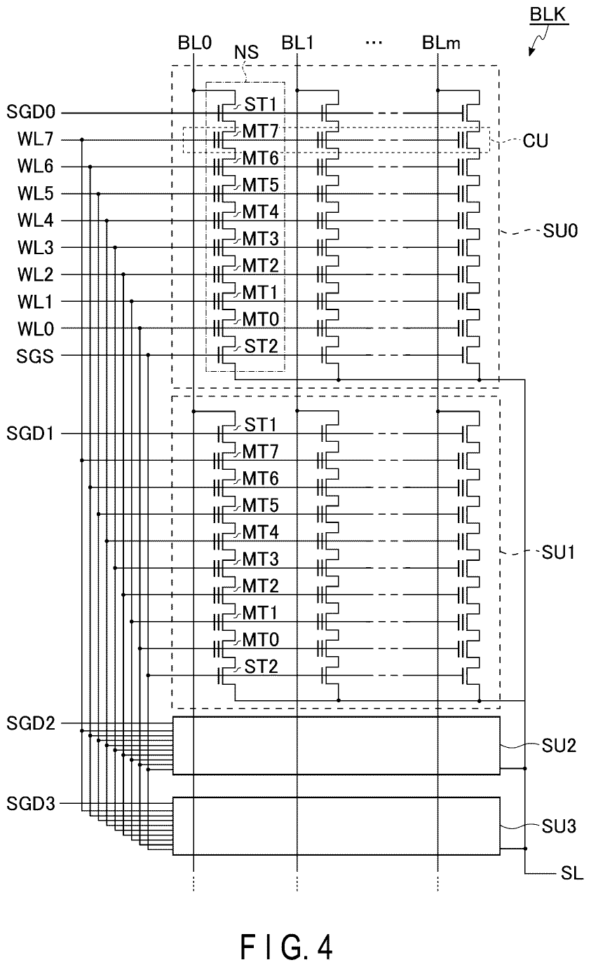

FIG. 4 is a circuit diagram illustrating an example of the circuit configuration of the memory cell array included in the semiconductor memory device according to the embodiment. FIG. 4 illustrates one block BLK. The block BLK includes, for example, four string units SU0 to SU3.

Each string unit SU includes a plurality of NAND strings NS that are associated with bit lines BL0 to BLm (m is an integer of 1 or more), respectively. Each NAND string NS includes, for example, eight memory cell transistors MT0 to MT7 and select transistors ST1 and ST2. Each memory cell transistor MT includes a control gate and a charge storage film, and stores data in a nonvolatile manner, based on the quantity of charge in the charge storage film. Each of the select transistors ST1 and ST2 is used to select the string unit SU at times of various operations.

In each NAND string NS, the memory cell transistors MT0 to MT7 are coupled in series in the named order. The drain of the select transistor ST1 is coupled to the associated bit line BL, and the source of the select transistor ST1 is coupled to the drain of the memory cell transistor MT7. The drain of the select transistor ST2 is coupled to the source of the memory cell transistor MT0, and the source of the select transistor ST2 is coupled to a source line SL.

The control gates of the memory cell transistors MT0 to MT7 in the same block BLK are coupled to the word lines WL0 to WL7, respectively. The gates of the select transistors ST1 in the string units SU0 to SU3 are coupled to select gate lines SGD0 to SGD3, respectively. The gates of the select transistors ST2 are coupled to the select gate line SGS.

Different column addresses CA are allocated to the bit lines BL0 to BLm. Each bit line BL is shared by the NAND strings NS to which an identical column address CA is allocated between a plurality of blocks BLK. Each of the word lines WL0 to WL7 is provided for each block BLK. The source line SL is shared by, for example, a plurality of blocks BLK.

A set of memory cell transistors MT, which are coupled to a common word line WL in one string unit SU, is referred to as, for example, “cell unit CU”. For example, a storage capacity of the cell unit CU including memory cell transistors MT each storing 1-bit data is defined as “one page data”. Each cell unit CU can have a storage capacity of two page data or more, in accordance with the number of bits of data that the memory cell transistor MT stores.

Note that the circuit configuration of the memory cell array 10 included in the semiconductor memory device 3 according to the embodiment is not limited to the circuit configuration described above. For example, the number of string units SU included in each block BLK can be designed to be a freely selected number. The number of memory cell transistors MT included in each NAND string NS, and the number of select transistors ST1 and ST2 included in each NAND string NS, can be designed to be freely selected numbers.

### 1.6. Configuration of Memory Cell Array

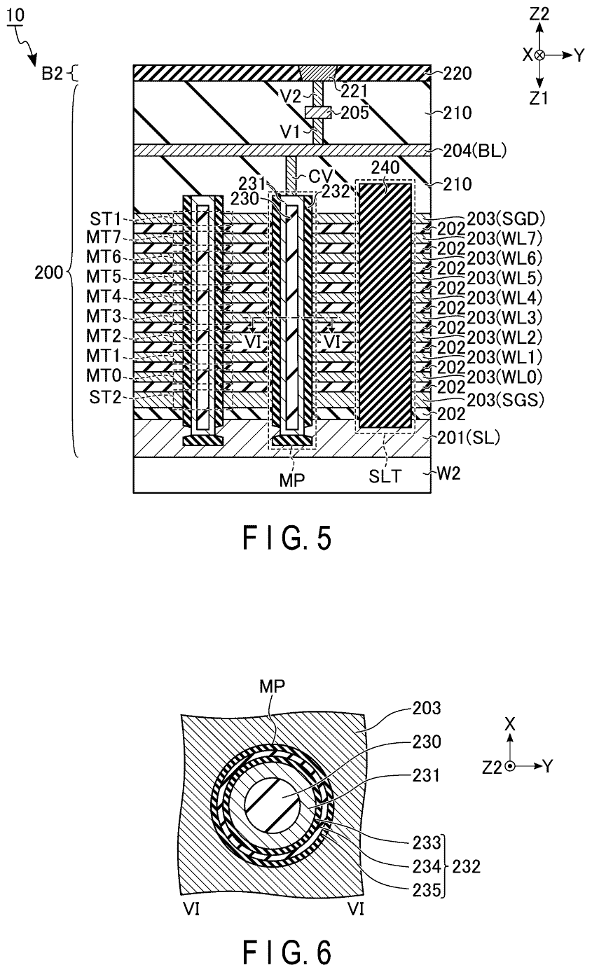

FIG. 5 is a cross-sectional view illustrating an example of a cross-sectional configuration of the memory cell array in the semiconductor memory device according to the embodiment. FIG. 5 illustrates a cross-sectional configuration of the memory layer 200 and the joint layer B2, which correspond to the memory cell array 10. Note that in FIG. 5, the Z1 direction (upward direction) is illustrated as a downward direction on the drawing sheet, and the Z2 direction (downward direction) is illustrated as an upward direction on the drawing sheet. In addition, in the description below, the direction in which the word lines WL0 to WL7 extend is defined as an X direction, and the direction in which the bit line BL extends is defined as a Y direction.

The memory cell array 10 includes a semiconductor layer 201, insulator layers 202, conductor layers 203, conductor layers 204 and 205, insulator layers 210 and 220, a conductor 221, contacts CV, V1 and V2, memory pillars MP, and a member SLT. The memory cell array 10 is formed by using the semiconductor substrate W2. The semiconductor layer 201 is provided on a surface of the semiconductor substate W2 in the Z2 direction. The semiconductor layer 201 functions as the source line SL. The semiconductor layer 201 includes, for example, silicon. The insulator layers 202 and the conductor layers 203 are alternately stacked one by one on a surface of the semiconductor layer 201 in the Z2 direction. In the example illustrated in FIG. 5, ten insulator layers 202 and ten conductor layers 203 are alternately stacked one by one. In other words, the conductor layers 203 stacked spaced apart in the Z direction are provided in the downward direction of the semiconductor layer 201 (in the upward direction on the drawing sheet). The conductor layers 203 extend in the X direction, and function as the select gate line SGS, word lines WL0 to WL7 and select gate line SGD in the order from the semiconductor substrate W2 side. The insulator layers 202 include, for example, silicon oxide (SiO). The conductor layers 203 include, for example, tungsten (W) or molybdenum (Mo). Below (above on the drawing sheet) in the Z2 direction of the lowermost (uppermost on the drawing sheet) conductor layer 203, the conductor layer 204 is provided via the insulator layer 210. The conductor layer 204 extends in the Y direction and functions as the bit line BL. The conductor layer 204 includes, for example, copper (Cu). The contact CV extends in the Z direction through the insulator layer 210, and couples a semiconductor film 231 of a memory pillar MP (to be described later) and the conductor layer 204. Below (above on the drawing sheet) the conductor layer 204, the conductor layer 205 is provided via the insulator layer 210. The contact V1 extends in the Z direction through the insulator layer 210, and couples the conductor layers 204 and 205. Below (above on the drawing sheet) the conductor layer 205, the joint layer B2 is provided via the insulator layer 210. The joint layer B2 includes the insulator layer 220 and the conductor 221. The conductor 221 corresponds to the joint pad provided in the joint layer B2. The contact V2 extends in the Z direction through the insulator layer 210 and couples the conductor layer 205 and the conductor 221. Specifically, the conductor layer 204 is coupled to the conductor 221 via the conductor layer 205 and the contacts V1 and V2.

Each of memory pillars MP has a cylindrical shape extending in the Z direction. One memory pillar MP corresponds to one NAND string NS. The memory pillars MP are provided in such a manner as to cross the conductor layers 203. A part of the memory pillar MP, which crosses the conductor layer 203 corresponding to the select gate line SGS, functions as the select transistor ST2. Parts of the memory pillar MP, which cross the conductor layers 203 corresponding to the word lines WL0 to WL7, function as the memory cell transistors MT0 to MT7. A part of the memory pillar MP, which crosses the conductor layer 203 corresponding to the select gate line SGD, functions as the select transistor ST1.

Each memory pillar MP includes a core film 230, the semiconductor film 231, and a stacked film 232. The core film 230 extends in the Z direction. For example, an end portion of the core film 230 in the Z1 direction is located in the semiconductor layer 201, and an end portion of the core film 230 in the Z2 direction is located in the insulator layer 210. The core film 230 includes, for example, an insulator such as silicon oxide. The semiconductor film 231, for example, surrounds a periphery of the core film 230. On a side surface of the memory pillar MP near an end portion in the Z1 direction, a part of the semiconductor film 231 is put in contact with, and is electrically coupled to, the semiconductor layer 201. An end portion of the semiconductor film 231 in the Z2 direction is coupled to the contact CV. The semiconductor film 231 includes, for example, silicon (Si). The stacked film 232 covers a side surface and an upper surface (a lower surface on the drawing sheet) of the semiconductor film 231, except for the part where the semiconductor film 231 is in contact with the semiconductor layer 201.

FIG. 6 is a cross-sectional view taken along line VI-VI in FIG. 5, FIG. 6 illustrating an example of a cross-sectional configuration of the memory pillar included in the semiconductor memory device according to the embodiment. To be more specific, FIG. 6 illustrates a cross-sectional configuration of the memory pillar MP in a layer including the conductor layer 203. As illustrated in FIG. 6, the stacked film 232 includes, for example, a tunnel insulating film 233, a charge storage film 234, and a block insulating film 235.

In a cross section including the conductor layer 203, the core film 230 is provided, for example, in a central portion of the memory pillar MP. The semiconductor film 231 surrounds a side surface of the core film 230. The tunnel insulating film 233 surrounds a side surface of the semiconductor film 231. The charge storage film 234 surrounds a side surface of the tunnel insulating film 233. The block insulating film 235 surrounds a side surface of the charge storage film 234. The conductor layer 203 surrounds a side surface of the block insulating film 235.

The semiconductor film 231 is used as a channel (current path) of the memory cell transistors MT0 to MT7 and the select transistors ST1 and ST2. Each of the tunnel insulating film 233 and block insulating film 235 includes, for example, silicon oxide. The charge storage film 234 includes, for example, silicon nitride (SiN). By this configuration, the memory pillar MP can function as one NAND string NS.

As illustrated in FIG. 5, the member SLT has a wall-shaped structure extending in the XZ plane, and separates the insulator layers 202 and the conductor layers 203 in the Y direction. For example, an end portion of the member SLT in the Z1 direction is located in the semiconductor layer 201, and an end portion of the member SLT in the Z2 direction is located in the insulator layer 210. The positions of the memory pillar MP and the member SLT in the Z direction may be, or may not be, on the same level with each other. The member SLT includes an insulator 240. The insulator 240 includes, for example, silicon oxide. Although not illustrated, a plurality of members SLT are arranged in the Y direction. Each of regions divided by the members SLT in the Y direction functions as one block BLK.

### 1.7. Configuration of Semiconductor Memory Device

Hereinafter, a configuration of the semiconductor memory device 3 according to the embodiment is described. In a plan view to be referred to below, in order to enhance the visibility of the drawing, hatching is added, but the hatching is not necessarily related to the materials or characteristics of structural elements to which the hatching is added.

### 1.7.1. Planar Layout

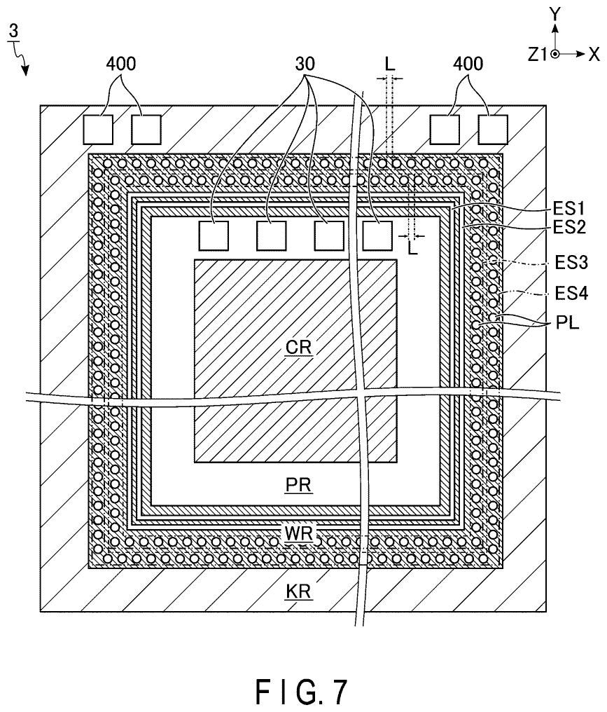

FIG. 7 is a plan view illustrating an example of a planar layout of the semiconductor memory device according to the embodiment. As illustrated in FIG. 7, the semiconductor memory device 3 includes, for example, a core region CR, a peripheral region PR, a wall region WR, and a kerf region KR.

The core region CR is, for example, a rectangular region provided near the center of the semiconductor memory device 3. In the core region CR, for example, the memory cell array 10, the register 13, the sequencer 14, the driver module 15, the row decoder module 16, and the sense amplifier module 17 are provided.

The peripheral region PR is a region having a rectangular loop shape, which is provided in such a manner as to surround an outer periphery of the core region CR. In the peripheral region PR, for example, the input/output circuit 11 and the logic control circuit 12 are provided. In addition, in the peripheral region PR, for example, contacts and interconnects for coupling interconnects provided in the interconnect layer 300 and circuits provided in the control circuit layer 100 or memory layer 200 are provided. Furthermore, a plurality of pads 30 are provided in the peripheral region PR.

The wall region WR is a region having a rectangular loop shape, which is provided in such a manner as to surround an outer periphery of the peripheral region PR. In the wall region WR, edge seals ES1 and ES2 are provided in such a manner as to surround the outer periphery of the peripheral region PR. In addition, edge seals ES3 and ES4 are provided in such a manner as to surround an outer periphery of the edge seals ES1 and ES2. The edge seals ES1 to ES4 include, for example, tungsten. Note that the number of edge seals corresponding to the edge seals ES1 and ES2 is freely selected, and may be one, or three or more. The number of edge seals corresponding to the edge seals ES3 and ES4 is freely selected, and may be one, or three or more. The details of the edge seals ES1 to ES4 will be described later.

The kerf region KR is a region having a rectangular loop shape, which is provided in such a manner as to surround an outer periphery of the wall region WR. The kerf region KF is in contact with an outermost periphery of the semiconductor memory device 3. In the kerf region KR, for example, an alignment mark used in the manufacturing process of the semiconductor memory device 3, and a TEG (Test Element Group) structure are arranged. For example, pads 400 may be provided in the kerf region KR. The pads 400 are a part of the TEG structure, and are used at a time of performing characteristic evaluation of the semiconductor memory device 3. Note that the alignment mark and the TEG structure including the pads 400 in the kerf region KR may not necessarily be provided. The structure of the kerf region KR may be removed at a time of performing a dicing step for dicing the semiconductor substrate W1 into chips (semiconductor memory devices 3).

### 1.7.2. Cross-Sectional Configuration

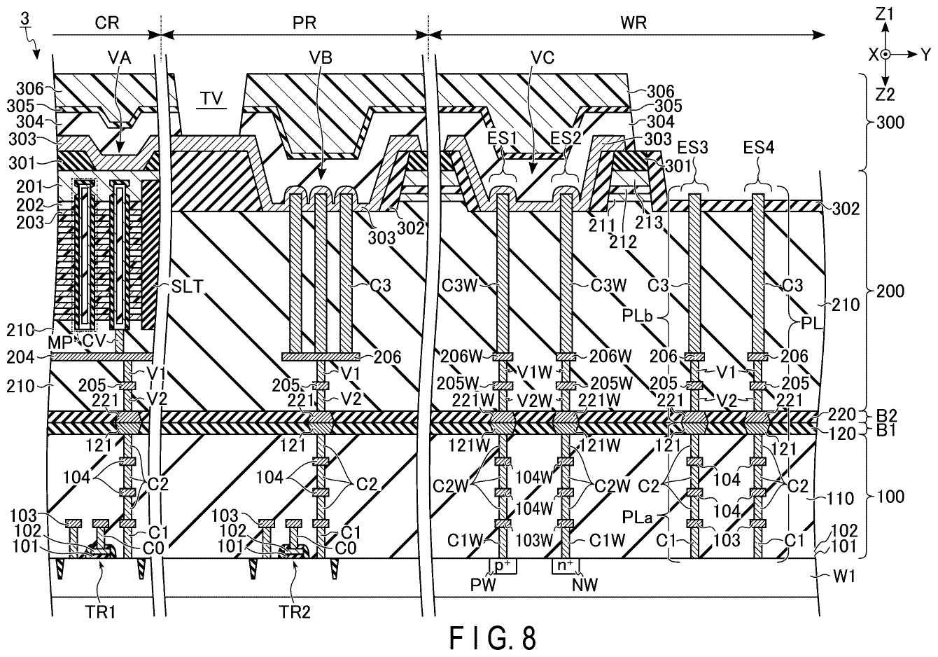

FIG. 8 is a cross-sectional view illustrating an example of a cross-sectional configuration of the semiconductor memory device according to the embodiment. FIG. 8 illustrates the core region CR, peripheral region PR and wall region WR after the semiconductor substrates W1 and W2 are bonded. Note that in the example illustrated in FIG. 8, after the semiconductor substrates W1 and W2 are bonded, the semiconductor substrate W2 is removed, and the interconnect layer 300 is formed in a part from which the semiconductor substrate W2 was removed.

### 1.7.2.1. Cross-Sectional Configuration of Control Circuit Layer

A cross-sectional configuration of the control circuit layer 100 and the joint layer B1 is described. The control circuit layer 100 includes an insulator layer 110, a gate insulating film 101, a gate electrode 102, conductor layers 103, 103W, 104 and 104W, and contacts C0, C1, C1W, C2 and C2W. The joint layer B1 includes an insulator layer 120, and conductors 121 and 121W. In addition, in the control circuit layer 100, a transistor TR1 is provided in the core region CR, and a transistor TR2 is provided in the peripheral region PR.

The insulator layer 110 is provided on the semiconductor substrate W1. The insulating layer 110 covers at least a part of interconnects, contacts, elements and the like provided in the control circuit layer 100. The insulating layer 110 includes, for example, TEOS (Tetra Ethoxy Silane). The insulator layer 110 may be composed of a plurality of kinds of insulating films. The insulator layer 120 is provided on the insulator layer 110. The insulator layer 120 covers side surfaces of the joint pads provided in the joint layer B1. The insulator layer 120 includes, for example, silicon oxide.

In the core region CR, the gate insulating film 101 is provided on the semiconductor substrate W1. The gate electrode 102 is provided on the gate insulating film 101. The gate insulating film 101 is used as a gate insulating film of the transistor TR1, and the gate electrode 102 is used as a gate electrode of the transistor TR1. The conductor layer 103 is provided in a layer above the gate electrode 102. The contact C0 couples the gate electrode 102 and the conductor layer 103. The contact C1 couples an impurity diffusion region of the transistor TR1, which is provided in the semiconductor substrate W1, and the conductor layer 103. The conductor layer 103 is coupled to the conductor 121 via at least one contact C2 and at least one conductor layer 104. The conductor 121 corresponds to the joint pad provided in the joint layer B1.

In the peripheral region PR, the gate insulating film 101, gate electrode 102, conductor layers 103 and 104, conductor 121 and contacts C0, C1 and C2 are provided in the same manner as in the core region CR. Specifically, the gate insulating film 101 is used as a gate insulating film of the transistor TR2, and the gate electrode 102 is used as a gate electrode of the transistor TR2. The contact C1 couples an impurity diffusion region of the transistor TR2, which is provided in the semiconductor substrate W1, and the conductor layer 103.

In the wall region WR, the semiconductor substrate W1 includes a P-type well region PW and an N-type well region NW. The P-type well region PW is a diffusion region of P-type impurities (p+) provided near an upper surface of the semiconductor substrate W1. The N-type well region NW is a diffusion region of N-type impurities (n+) provided near an upper surface of the semiconductor substrate W1. In the wall region WR, the conductor layers 103W and 104W, conductors 121W, and contacts C1W and C2W are provided in accordance with the edge seals ES1 and ES2, respectively. Specifically, the contact C1W corresponding to the edge seal ES1 couples the P-type well region PW and the conductor layer 103W. The contact C1W corresponding to the edge seal ES2 couples the N-type well region NW and the conductor layer 103W. In addition, the conductor layers 103 and 104, conductors 121, and contacts C1 and C2 are provided in accordance with the edge seals ES3 and ES4, respectively. The contacts C1 corresponding to the edge seals ES3 and ES4 are in contact with the semiconductor substrate W1 at the lower surfaces of the contacts C1, but are not electrically coupled to the semiconductor substrate W1, since the parts of the contact in the semiconductor substrate W1 are not doped with impurities. The conductor layers 103 and 104, conductors 121 and contacts C1 and C2, which correspond to the edge seals ES3 and ES4, are successively provided in the Z direction, and form pillar structures PLa. Each of the pillar structures PLa has, for example, a structure of a cylindrical shape or an elliptic cylindrical shape with a circular or elliptic cross section in the XY plane. Note that the shape of each pillar structure PLa is not limited to this. For example, each pillar structure PLa may have a structure of a quadratic prism shape. Note that in the wall region WR, neither the gate insulating film 101 nor the gate electrode 102 is provided.

### 1.7.2.2. Cross-Sectional Configuration of Memory Layer

A cross-sectional configuration of the memory layer 200 and the joint layer B2 is described. The memory layer 200 includes insulator layers 202 and 210, semiconductor layers 201, 211 and 213, conductor layers 203, 204, 205, 205W, 206 and 206W, a sacrificial member 212, and contacts C3, C3W, CV, V1, V1W, V2 and V2W. The joint layer B2 includes an insulator layer 220, and conductors 221 and 221W.

The insulator layer 220 is provided on the insulator layer 120. The insulator layer 220 covers side surfaces of the joint pads provided in the joint layer B2. The insulator layer 220 includes, for example, silicon oxide. The insulator layer 210 is provided on the insulator layer 220. The insulating layer 210 covers at least a part of interconnects, contacts, elements and the like provided in the memory layer 200. The insulating layer 210 includes, for example, TEOS. The insulator layer 210 may be composed of a plurality of kinds of insulating films. For example, the insulating layer 210 may have such a configuration that layers including silicon oxide and layers including silicon nitride are alternately stacked.

The conductors 221 correspond to the joint pads provided in the joint layer B2. The control circuit layer 100 and the memory layer 200 are bonded such that the conductors 121 and 221 are coupled to each other at a boundary surface between the joint layers B1 and B2.

In the core region CR, the memory cell array 10 is provided. The memory pillar MP included in the memory cell array 10 is coupled to the transistor TR1 via the conductor layers 103, 104, 204 and 205, conductors 121 and 221, and contacts CV, C1, C2, C3, V1 and V2.

In the peripheral region PR, the conductor layers 205 and 206, semiconductor layers 211 and 213, sacrificial member 212, conductor 221 and contacts C3, V1 and V2 are provided. The semiconductor layers 211 and 213 and the sacrificial member 212 are provided at a position corresponding to the position in the Z direction where the semiconductor layer 201 in the core region CR is provided. On the insulator layer 210, the semiconductor layer 211, sacrificial member 212 and semiconductor layer 213 are stacked in the named order. The semiconductor layer 201 of the core region CR corresponds to a structure in which the sacrificial member 212 is replaced with a conductor after the semiconductor layer 211, sacrificial member 212 and semiconductor layer 213 are stacked. Each of the semiconductor layer 211 and 213 includes, for example, polysilicon. The sacrificial member 212 includes, for example, silicon nitride. The conductor layer 206 is an interconnect that is provided on the same level as the conductor layer 204. At least one contact C3 is provided above the conductor layer 206. An upper end of each of the contacts C3 reaches at least the height of the semiconductor layer 211, is provided in such a manner as to be covered by a conductor layer 303 of the interconnect layer 300 (to be described later), and is electrically coupled to the conductor layer 303. The conductor layer 206 is electrically coupled to the conductor 221 via the conductor layer 205 and the contacts V1 and V2. Thereby, the conductor layer 303 is coupled to the transistor TR2 via the conductor layers 103, 104, 205 and 206, conductors 121 and 221, and contacts C1, C2, C3, V1 and V2.

In the wall region WR, the conductor layers 205W and 206W, conductor 221W and contacts C3W, V1W and V2W are provided in accordance with the edge seals ES1 and ES2. An upper end of each of the contacts C3W corresponding to the edge seals ES1 and ES2 reaches at least the height of the semiconductor layer 211, is provided in such a manner as to be covered by the conductor layer 303 of the interconnect layer 300 (to be described later), and is electrically coupled to the conductor layer 303. In addition, the conductor layers 205 and 206, conductor 221 and contacts C3, V1 and V2 are provided in accordance with the edge seals ES3 and ES4. An upper end of each of the contacts C3 corresponding to the edge seals ES3 and ES4 penetrates, for example, an insulating layer 302 in the interconnect layer 300 (to be described later), and is exposed to a surface of the semiconductor memory device 3. Note that it is not always necessary that all of the contacts C3 corresponding to the edge seals ES3 and ES4 be exposed to the surface of the semiconductor memory device 3. For example, an upper end of a part of the contacts C3, which corresponds to the edge seal ES3, may be covered by an insulator layer 302, 304, 305 or 306 (to be described later). The conductor layers 205 and 206, conductor 221 and contacts C3, V1 and V2, which correspond to each of the edge seals ES3 and ES4, are successively provided in the Z direction, and form a pillar structure PLb. Each of the pillar structures PLb has, for example, a structure of a cylindrical shape or an elliptic cylindrical shape with a circular or elliptic cross section in the XY plane. Note that the shape of each pillar structure PLb is not limited to this. For example, each pillar structure PLb may have a structure of a quadratic prism shape.

### 1.7.2.3. Cross-Sectional Configuration of Interconnect Layer

A cross-sectional configuration of the interconnect layer 300 is described. The interconnect layer 300 includes insulator layers 301, 302, 304, 305 and 306, and a conductor layer 303. The insulator layer 301 is provided on the semiconductor layers 201 and 213. In a part of the peripheral region PR, in a part of the wall region WR and in the kerf region KR, the insulator layer 302 is provided in such a manner as to penetrate the insulator layer 301, semiconductor layer 213, sacrificial member 212 and semiconductor layer 211. An upper surface of the insulator layer 302 may be flush with an upper surface of the insulator layer 301, or a step may be formed between the insulator layers 301 and 302. In parts of the core region CR, peripheral region PR, and wall region WR, the conductor layer 303 is stacked above the insulator layers 301 and 302. The conductor layer 303 is divided (insulated) at least between the peripheral region PR and the wall region WR in the cross section shown in the FIG. 8. The conductor layer 303 may include a portion that is provided continuously between the core region CR and the peripheral region PR. In parts of the core region CR, peripheral region PR and wall region WR, the insulator layers 304, 305 and 306 are stacked in the named order, above the insulator layer 301 or the conductor layer 303. In other words, in a part of the wall region WR and in the kerf region KR, there may be a region where the insulator layers 304, 305 and 306 are not provided. Specifically, above the edge seals ES3 and ES4, and in the kerf region KR, the insulator layers 304, 305 and 306 are not provided. The insulator layers 301, 302 and 304 include, for example, silicon oxide. The insulator layer 305 includes, for example, silicon nitride. The insulator layer 306 includes, for example, polyimide. The insulating layers 305 and 306 function as passivation films that protect the surface of the semiconductor memory device 3.

In the core region CR, an opening portion VA is provided. The opening portion VA is a trench that is formed in such a manner as to penetrate the insulator layer 301. The conductive layer 303 is electrically coupled to the semiconductor layer 201 via the opening portion VA. The conductor layer 303 and the insulator layers 304, 305 and 306 include portions that are provided along the opening portion VA.

In the peripheral region PR, opening portions VB and TV are provided. The opening portion VB is a trench that is provided above the contacts C3 coupled to the transistor TR2, and that is formed in such a manner as to penetrate the insulator layer 301, sacrificial member 212 and semiconductor layers 211 and 213. The conductor layer 303 is electrically coupled to the contacts C3 via the opening portion VB. In this case, the conductor layer 303 is provided in such a manner as to cover upper parts of the contacts C3. Since a side portion of the opening portion VB is covered by the insulating layer 302, the conductor layer 303 and the semiconductor layers 211 and 213 are insulated from each other. The conductor layer 303 and insulating layers 302, 304, 305 and 306 include portions that are provided along the opening portion VB. The opening portion TV is a trench that is formed in such a manner as to penetrate the insulating layers 304, 305 and 306. The conductor layer 303 is exposed at a bottom portion of the opening portion TV. A part at which the conductor layer 303 is exposed in the bottom portion of the opening portion TV functions as the pad 30. The insulating layer 302 is provided under the part at which the surface of the conductor layer 303 is exposed in the bottom portion of the opening portion TV. In other words, the part at which the surface of the conductor layer 303 is exposed in the bottom portion of the opening portion TV does not include a portion overlapping the semiconductor layer 201 and the semiconductor layers 211 and 213 in the Z direction. The opening portions VB and TV may be provided at positions that do not overlap each other in the Z direction, or may be provided to overlap each other in the Z direction.

In the wall region WR, an opening portion VC is provided. The opening portion VC is a trench that is provided above the contacts C3W corresponding to the edge seals ES1 and ES2, and is formed in such a manner as to penetrate the insulating layer 301, sacrificial member 212 and semiconductor layers 211 and 213. The conductor layer 303 is electrically coupled to the contacts C3W corresponding to the edge seals ES1 and ES2 via the opening portion VC. At this time, the conductor layer 303 is provided in such a manner as to cover upper portions of the contacts C3W. Since a side portion of the opening portion VC is covered by the insulator layer 302, the conductor layer 303 and the semiconductor layers 211 and 213 are insulated from each other. The conductor layer 303 and the insulating layers 302, 304, 305 and 306 include portions that are provided along the opening portion VC.

### 1.7.3. Configuration of Edge Seals

Referring to FIG. 7 and FIG. 8, a configuration of the edge seals ES1 to ES4 is described.

As illustrated in FIG. 8, the conductor 121W and conductor 221W corresponding to the edge seal ES1 are coupled to each other at a boundary between the joint layers B1 and B2. Specifically, the edge seal ES1 includes a wall-shaped structure that is composed of the conductor layers 103W, 104W, 205W and 206W, conductors 121W and 221W and contacts C1W, C2W, C3W, V1W and V2W, which are provided from the control circuit layer 100 to the memory layer 200. Similarly, the conductor 121W and conductor 221W corresponding to the edge seal ES2 are coupled to each other at a boundary between the joint layers B1 and B2. Specifically, the edge seal ES2 includes a wall-shaped structure that is composed of the conductor layers 103W, 104W, 205W and 206W, conductors 121W and 221W and contacts C1W, C2W, C3W, V1W and V2W, which are provided from the control circuit layer 100 to the memory layer 200.

The conductor 121 and conductor 221 corresponding to the edge seal ES3 are coupled to each other at a boundary between the joint layers B1 and B2. Specifically, the pillar structures PLa and PLb corresponding to the edge seal ES3 are coupled in the Z direction, thereby forming a single pillar structure PL. Similarly, the conductor 121 and conductor 221 corresponding to the edge seal ES4 are coupled to each other at a boundary between the joint layers B1 and B2. Specifically, the pillar structures PLa and PLb corresponding to the edge seal ES4 are coupled in the Z direction, thereby forming a single pillar structure PL.

As illustrated in FIG. 7, the edge seals ES1 and ES2 are conductors having rectangular loop shapes extending in the XZ plane or YZ plane. Specifically, at a position where the edge seals ES1 and ES2 neighbor the peripheral region PR in the X direction, the edge seals ES1 and ES2 extend in the YZ plane direction. At a position where the edge seals ES1 and ES2 neighbor the peripheral region PR in the Y direction, the edge seals ES1 and ES2 extend in the XZ plane direction. The edge seal ES1 is continuously provided in such a manner as to surround the peripheral region PR. The edge seal ES2 is continuously provided in such a manner as to surround the edge seal ES1. Even in a case where each of the edge seals ES1 and ES2 is discontinuous only partly, each of the edge seals ES1 and ES2 may be interpreted as being continuously provided. Each of the edge seals ES1 and ES2 has a wall shape.

The edge seals ES3 and ES4 have such a configuration that the pillar structures PL, which are pillar-shaped conductors extending in the Z direction, are spaced apart and arranged in the X direction or Y direction. Specifically, at a position where the edge seals ES3 and ES4 neighbor the peripheral region PR in the X direction, the edge seals ES3 and ES4 have such a configuration that the pillar structures PL are spaced apart and arranged in the Y direction. At a position where the edge seals ES3 and ES4 neighbor the peripheral region PR in the Y direction, the edge seals ES3 and ES4 have such a configuration that the pillar structures PL are spaced apart and arranged in the X direction. In the description below, the direction in which pillar structures PL are arranged is referred to as an alignment direction. The pillar structures PL corresponding to the edge seal ES3 and the pillar structures PL corresponding to the edge seal ES4 are arranged, for example, in a staggered fashion. The edge seal ES3 is provided in such a manner as to surround the edge seal ES2 in a rectangular loop shape. The edge seal ES4 is provided in such a manner as to surround the edge sheal ES3 in a rectangular loop shape. Tip ends of the edge seals ES3 and ES4 are exposed from the insulator layers 305 and 306. In addition, the tip ends of the edge seals ES3 and ES4 are put in direct contact with the resin layer 7.

Each of the pillar structures PL included in the edge seals ES3 and ES4 has, for example, in plan view, a circular shape with a diameter of 200 nm to 400 nm, or an elliptic shape with a major axis and a minor axis of similar dimensions. More preferably, each of the pillar structures PL has, in plan view, a circular shape with a diameter of 250 nm to 350 nm, or an elliptic shape with a major axis and a minor axis of similar dimensions. In this case, as illustrated in FIG. 7, a distance L between nearest pillar structures PL arranged in the alignment direction of pillar structures PL is in a range of about 100 nm to about 300 nm. More preferably, the distance L between nearest pillar structures PL arranged in the alignment direction of pillar structures PL is in a range of about 150 nm to about 250 nm. In the present embodiment, the diameter of each of the pillar structures PL is 300 nm, and the distance, or the pitch, between nearest pillar structures PL arranged in the alignment direction is 200 nm. The diameter of each of the pillar structures PL and the distance between nearest pillar structures PL arranged in the alignment direction are not limited to these.

Preferably, the length (width) of the diameter of each of the pillar structures PL is equal to or less than the width of the interconnect 6. Note that each pillar structure PL may have any shape if the length (width) of the diameter in the alignment direction at the part exposed to the outside is equal to or less than the width of the interconnect 6. For example, each pillar structure PL may have a square shape or a rectangular shape in plan view.

The edge seals ES1 to ES4 function as crack stoppers that prevent defects, such as film peeling or chipping occurring at a time of dicing, from entering the core region CR and peripheral region PR. In addition, the edge seals ES1 and ES2 have an effect of preventing moisture or ion molecules from entering the core region CR and peripheral region PR from the outside of the semiconductor memory device 3. Furthermore, the edge seals ES1 and ES2 function to release positive charge and negative charge occurring inside and outside the wall region WR to the semiconductor substrate W1.

Note that each of all pillar structures PL included in the edge seals ES3 and ES4 may not necessarily be electrically coupled in the Z direction. For example, the conductors 121 and 221 corresponding to the edge seals ES3 and ES4 may not be provided. Parts of the pillar structures PL included in the edge seals ES3 and ES4 may be divided in the Z direction by an insulator.

### 2. Description of Advantageous Effects

The semiconductor memory device 3 according to the embodiment can improve the yield. This advantageous effect is described below in detail.

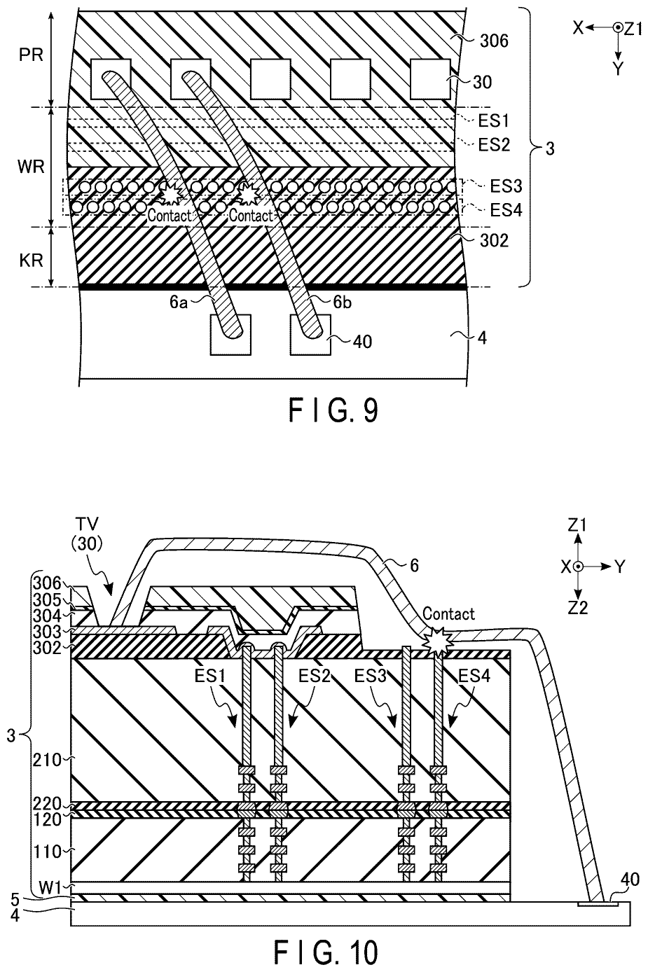

FIG. 9 is a plan view illustrating an example of a connection between the semiconductor memory device according to the embodiment and the wiring board. FIG. 10 is a cross-sectional view illustrating an example of a connection between the semiconductor memory device according to the embodiment and the wiring board. Note that in FIG. 9 and FIG. 10, for the purpose of simplicity, some structures are omitted. As illustrated in FIG. 9 and FIG. 10, the pads 30 of the semiconductor memory device 3 and the pads 40 of the wiring board 4 are electrically coupled via interconnects 6.

The manufacturing steps of the semiconductor memory device include a dicing step for singulating a plurality of semiconductor memory devices formed on a single wafer. In the dicing step, a method of physical cutting along a dicing line with use of a blade is generally adopted, but there is possibility that defects, such as film peeling and chipping, occur near a cutting surface. If such defects progress to main parts (for example, the memory cell array and control circuit provided in the core region) of the semiconductor memory device, there is a possibility that the capability of the semiconductor memory device 3 is adversely affected.

The edge seals are formed in order to prevent such defects as film peeling and chipping from progressing into the main parts of the semiconductor memory device. The edge seals include, for example, a metal such as tungsten, and are provided in such a manner as to form wall portions surrounding the outer periphery of the main parts of the semiconductor memory device. By the edge seals, it is possible to prevent defects, such as film peeling and chipping, from entering the main parts of the semiconductor memory device 3.

However, depending on the structure of the semiconductor memory device, there is a case where some edge seals have to be disposed in a region that cannot be covered by a passivation film or the like. In the semiconductor memory device 3 according to the embodiment, as illustrated in FIG. 9 and FIG. 10, the upper end portions of the edge seals ES1 and ES2 are covered by the insulating layers 304 to 306 and are not exposed. On the other hand, the insulating layer 306 is not provided above the edge seals ES3 and ES4. The reason for this is that the insulating layer 306 hinders dicing in the dicing step and thus a region where the insulating layer 306 is not provided is formed at a predetermined distance from the dicing line. In addition, the insulating layers 302, 304 and 305 provided above the edge seals ES3 and ES4 are removed by over-etching at a time of forming the opening portion TV. Thus, the upper end portions of the edge seals ES3 and ES4 are exposed.

There is a case where the interconnects 6 that couple the pads 30, and the pads 40 of the wiring board 4, pass over the edge seals ES3 and ES4. In this case, as illustrated in FIG. 9 and FIG. 10, there is a possibility that some interconnects 6 come in contact with exposed portions of the upper end portions of the edge seal ES3 or ES4.

In a case where the structures corresponding to the edge seals ES3 and ES4 are provided in wall shapes, for example, like the edge seals ES1 and ES2, the plurality of interconnects 6 are electrically coupled at a time when each of the plurality of interconnects 6 comes in contact with the same one of the upper end portions of the edge seal ES3 or ES4. As a result, since the pads 30 having different potentials are short-circuited, there is a possibility that the circuit interconnects are broken.

On the other hand, in the semiconductor memory device 3 according to the present embodiment, the edge seals ES3 and ES4 have such a configuration that the pillar structures PL are arranged, and the pillar structures PL are electrically insulated from each other. Thus, as illustrated in FIG. 9, even in a case where the interconnects 6 (interconnects 6a and 6b) come in contact with the upper end portions of the edge seal ES3 or ES4, if the pillar structures PL, with which the interconnects 6 come in contact, are different, the interconnects 6 are not electrically coupled. In addition, the length of the upper end portion of each pillar structure PL in the alignment direction is equal to or less than the width of the interconnect 6, and thus, in each pillar structure PL, the number of interconnects 6, which pass over a position overlapping the pillar structure PL in the Z direction, is one at most. Therefore, short-circuit between the pads 30 having different potentials can be prevented, and breakage of the circuit interconnect can be suppressed. In other words, the yield of semiconductor memory devices 3 can be improved.

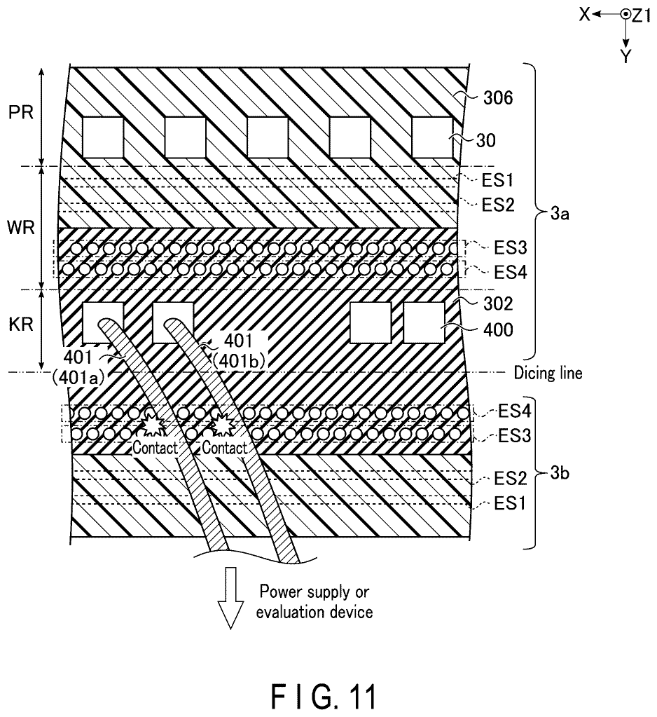

Furthermore, the semiconductor memory device 3 according to the present embodiment can improve the accuracy in a case of executing characteristic evaluation. FIG. 11 is a plan view illustrating an example of a planar layout in a case of executing characteristic evaluation in the semiconductor memory device according to the embodiment. Note that the semiconductor memory device 3 illustrated in FIG. 11 is in a state in which a plurality of chips (semiconductor memory devices 3a and 3b) are arranged and formed on a single semiconductor substrate W1 before the dicing step.

For example, the characteristic evaluation of the semiconductor memory device is performed by using the TEG structure. Pads 400 corresponding to the TEG structure are coupled to, for example, an external power supply or an evaluation device via interconnects 401. The interconnects 401 are, for example, bonding wires each having a width substantially equal to the width of the interconnect 6. At this time, for example, there is a case where the interconnects 401 pass over the edge seals ES3 and ES4. In this case, as illustrated in FIG. 11, there is a possibility that some of the interconnects 401 come in contact with exposed portions of the upper end portions of the edge seal ES3 or ES4.

In the semiconductor memory device 3 according to the present embodiment, the edge seals ES3 and ES4 have such a configuration that the pillar structures PL are arranged, and the pillar structures PL are electrically insulated from each other. Thus, as illustrated in FIG. 11, even in a case where the interconnects 401 (interconnects 401a and 401b) come in contact with the upper end portions of the edge seal ES3 or ES4, if the pillar structures PL, with which the interconnects 401 come in contact, are different, the interconnects 401 are not electrically coupled. In addition, the length in plan view of the upper end portion of each pillar structure PL in the alignment direction is sufficiently small, and thus, in each pillar structure PL, the number of interconnects 401, which pass over the pillar structure PL, is one at most. Therefore, short-circuit between the pads 400 having different potentials can be prevented. Thus, appropriate characteristic evaluation of the semiconductor memory devices 3 can be executed.

### 3. Modifications

The semiconductor memory device 3 according to the above-described embodiment can variously be modified. Hereinafter, a first modification, a second modification and a third modification of the embodiment are described with respect to points different from the embodiment.

### 3.1. First Modification

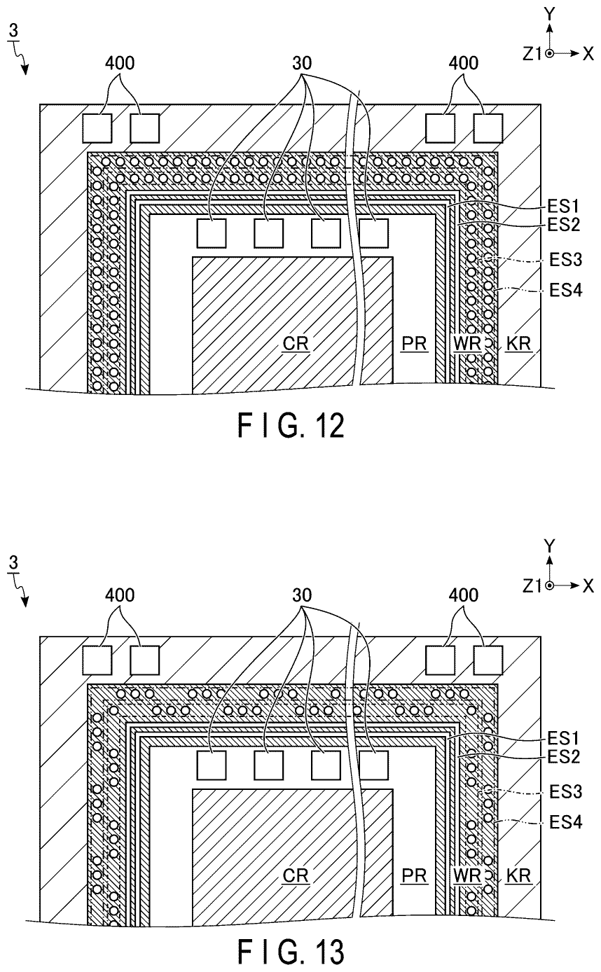

FIG. 12 is a plan view illustrating an example of a planar layout of a semiconductor memory device according to a first modification of the embodiment. FIG. 12 corresponds to a part of FIG. 7 in the embodiment.

As illustrated in FIG. 12, in the semiconductor memory device 3 according to the first modification of the embodiment, the arrangement of the pillar structures PL corresponding to the edge seals ES3 and ES4 is a regular square arrangement. Specifically, the pillar structures PL corresponding to the edge seal ES3 and the pillar structures PL corresponding to the edge seal ES4 are regularly arranged in the X direction and Y direction.

Like the semiconductor memory device 3 according to the embodiment, the semiconductor memory device 3 according to the first modification of the embodiment can improve the yield.

### 3.2. Second Modification

FIG. 13 is a plan view illustrating an example of a planar layout of a semiconductor memory device according to a second modification of the embodiment. FIG. 13 corresponds to a part of FIG. 7 in the embodiment.

As illustrated in FIG. 13, in the semiconductor memory device 3 according to the second modification of the embodiment, the pillar structures PL corresponding to the edge seals ES3 and ES4 are disposed in a staggered fashion in units of several pillar structures. In the example illustrated in FIG. 13, a plurality of pillar units, in each of which three pillar structures PL are arranged, are arranged in a staggered fashion in the edge seals ES3 and ES4, as viewed in the X direction or Y direction. The pillar units are arranged, for example, with a pitch of 800 nm to 1700 nm in the alignment direction. The arrangement of the pillar structures PL, the number of pillar structures PL, which form the pillar unit, and the pitch between the pillar units, are determined in accordance with, for example, the size of the pad 30, and the distance (pitch) with which the pads 30 are arranged.

Like the semiconductor memory device 3 according to the embodiment, the semiconductor memory device 3 according to the second modification of the embodiment can improve the yield.

### 3.3. Third Modification

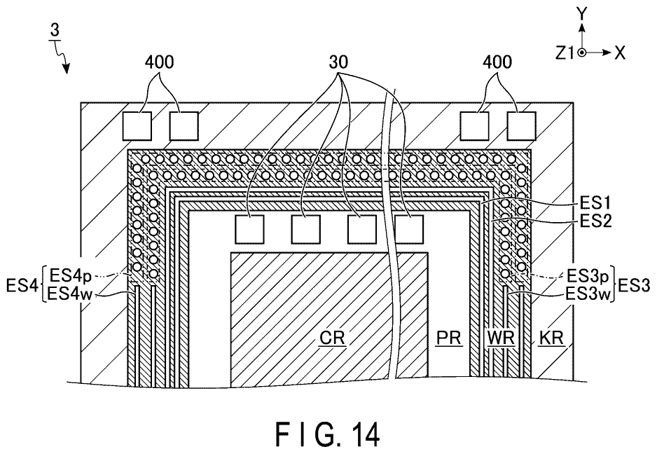

FIG. 14 is a plan view illustrating an example of a planar layout of a semiconductor memory device according to a third modification of the embodiment. FIG. 14 corresponds to a part of FIG. 7 in the embodiment.

As illustrated in FIG. 14, in the semiconductor memory device 3 according to the third modification of the embodiment, the edge seal ES3 includes a pillar portion ES3p and a wall portion ES3w. The edge seal ES4 includes a pillar portion ES4p and a wall portion ES4w. The pillar portions ES3p and ES4p of the edge seals ES3 and ES4 have the same configuration as the edge seals ES3 and ES4 in the semiconductor memory device 3 according to the embodiment. Specifically, the pillar portions ES3p and ES4p have such a configuration that the pillar structures PL are arranged in the X direction or Y direction. The pillar portions ES3p and ES4p are formed, for example, in a region over which the interconnects 6 pass. The wall portions ES3w and ES4w of the edge seals ES3 and ES4 have the same configuration as the edge seals ES1 and ES2 in the semiconductor memory device 3 according to the embodiment. Specifically, the wall portions ES3w and ES4w have wall-shaped structures formed by coupling, in the Z direction, conductors extending in the X direction or Y direction. The wall portions ES3w and ES4w are formed, for example, in a region over which the interconnects 6 do not pass. The edge seal ES3 is provided such that the pillar portion ES3p and the wall portion ES3w surround the edge seal ES2 in a rectangular loop shape. The edge seal ES4 is provided such that the pillar portion ES4p and the wall portion ES4w surround the edge seal ES3 in a rectangular loop shape.

Like the semiconductor memory device 3 according to the embodiment, the semiconductor memory device 3 according to the third modification of the embodiment can improve the yield. Furthermore, in the region where the wall portions ES3w and ES4w of the edge seals ES3 and ES4 are provided, the edge seals ES3 and ES4 can prevent the entrance of moisture or ion molecules from the outside of the semiconductor memory device 3, and the yield of semiconductor memory devices 3 can further be improved.

Note that in the example illustrated in FIG. 14, a single row of pillar structures PL is provided in the pillar portion ES3p or ES4p in association with one wall portion ES3w or ES4w. However, a plurality of rows of pillar structures PL may be provided in the pillar portion ES3p or ES4p. In addition, another row of pillar structures PL may be provided between the pillar portions ES3p and ES4p.

### 4. Others.

In the above-described embodiment and modifications, the structure of the semiconductor memory device was described as an example of the semiconductor device, but the embodiment and modifications are not limited to this. The function of the semiconductor device may be freely selected as long as the semiconductor device includes the structure that corresponds to the edge seals ES1 to ES4 in the embodiment and that surrounds the outer periphery of the main part of the semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a substrate having a major surface, the substrate including a first region, and a second region provided in such a manner as to surround an outer periphery of the first region as viewed in a first direction, the first direction being a direction perpendicular to the major surface;
a semiconductor circuit provided in the first region on the substrate;
a plurality of first conductive pillars provided in the second region on the substrate, spaced apart from each other and arranged in such a manner as to surround the first region, the first conductive pillars extending in the first direction, being electrically insulated from each other and being insulated from the semiconductor circuit; and
a passivation film provided in the first region and overlapping the semiconductor circuit in the first direction, the passivation film being provided on an opposite side to the substrate in the first direction with respect to the semiconductor circuit and the first conductive pillars,
wherein at least a part of the first conductive pillars is exposed from the passivation film.

2. The semiconductor device according to claim 1, wherein
the substrate further includes a third region between the first region and the second region, the third region being provided in such a manner as to surround an outer periphery of the first region, as viewed in the first direction,
the third region on the substrate further includes a first conductor that is insulated from the first conductive pillars and provided in a wall shape extending in the first direction and surrounding the first region,
the passivation film overlaps the first conductor in the first direction, and
the first conductive pillars are provided outside the first conductor with respect to the first region.

3. The semiconductor device according to claim 1, wherein at least a part of the first conductive pillars is in direct contact with a resin covering the substrate.

4. The semiconductor device according to claim 1, further comprising:
a plurality of pads provided, respectively, in a plurality of opening portions passing through the passivation film in the first direction in the first region, each of the pads being coupled to the semiconductor circuit; and
a plurality of interconnects coupled at one end to the pads and coupled at the other end to external terminals, wherein
the interconnects pass over positions overlapping some of the first conductive pillars in the first direction, and
a number of the interconnects overlapping each of the first conductive pillars in the first direction is one at most.

5. The semiconductor device according to claim 1, wherein each of the first conductive pillars has a circular shape or an elliptic shape as viewed in the first direction.

6. The semiconductor device according to claim 5, wherein each of the first conductive pillars has a diameter of 250 nm to 350 nm as viewed in the first direction.

7. The semiconductor device according to claim 1, wherein each of the first conductive pillars includes portions that are divided in the first direction and electrically insulated.

8. The semiconductor device according to claim 1, further comprising a plurality of second conductive pillars provided in the second region on the substrate, spaced apart from each other and arranged in such a manner as to surround the first region, the second conductive pillars extending in the first direction, being electrically insulated from each other and being insulated from the first conductive pillars and the semiconductor circuit, wherein
the second conductive pillars are provided outside the first conductive pillars with respect to the first region.

9. The semiconductor device according to claim 8, wherein the first conductive pillars and the second conductive pillars are arranged in a staggered fashion, as viewed in the first direction.

10. The semiconductor device according to claim 8, wherein the first conductive pillars and the second conductive pillars are disposed in a regular square arrangement fashion, as viewed in the first direction.

11. The semiconductor device according to claim 8, further comprising a plurality of first pillar units in each of which some mutually neighboring first conductive pillars of the first conductive pillars are arranged, and a plurality of second pillar units in each of which some mutually neighboring second conductive pillars of the second conductive pillars are arranged, wherein
the first pillar units and the second pillar units are arranged in a staggered fashion, as viewed from the first direction.

12. The semiconductor device according to claim 1, further comprising a second conductor provided in the second region, insulated from the first conductive pillars, extending in the first direction, and provided continuously in a wall shape in such a manner as to surround the first region together with the first conductive pillars.

13. The semiconductor device according to claim 12, further comprising:
a plurality of pads provided, respectively, in a plurality of opening portions passing through the passivation film in the first direction in the first region, each of the pads being coupled to the semiconductor circuit; and
a plurality of interconnects coupled at one end to the pads and coupled at the other end to external terminals, wherein
the interconnects pass over positions overlapping some of the first conductive pillars in the first direction, and do not pass over a position overlapping the second conductor in the first direction, and
a number of the interconnects overlapping each of the first conductive pillars in the first direction is one at most.

14. The semiconductor device according to claim 1, wherein the passivation film includes polyimide.

15. A semiconductor device comprising:
a substrate having a major surface, the substrate including a first region, and a second region provided in such a manner as to surround an outer periphery of the first region as viewed in a first direction, the first direction being a direction perpendicular to the major surface;
a semiconductor circuit provided in the first region on the substrate;
a first conductive pillar extending in the first direction in the second region on the substrate;
a passivation film provided in the first region and overlapping the semiconductor circuit in the first direction, the passivation film being provided on an opposite side to the substrate in the first direction with respect to the semiconductor circuit and the first conductive pillar;
a pad provided in an opening portion passing through the passivation film in the first direction in the first region, and coupled to the semiconductor circuit; and
an interconnect coupled at one end to the pad and coupled at the other end to an external terminal, wherein
the first conductive pillar is exposed from the passivation film,
at least a part of the interconnect passes over a position overlapping the first conductive pillar in the first direction, and
a width of the first conductive pillar as viewed in the first direction is equal to or less than a width of the interconnect.

16. The semiconductor device according to claim 15, further comprising a plurality of conductive pillars including the first conductive pillar, the conductive pillars being provided in the second region on the substrate and extending in the first direction, wherein
the conductive pillars are exposed from the passivation film,
at least a part of the interconnect passes over a position overlapping any one of the conductive pillars in the first direction,
a width of each of the conductive pillars as viewed in the first direction is equal to or less than a width of the interconnect, and
at least a part of the conductive pillars is provided in the second region on the substrate, electrically insulated from each other, spaced apart from each other and arranged in such a manner as to surround the first region.

17. The semiconductor device according to claim 15, wherein
the substrate further includes a third region between the first region and the second region, the third region being provided in such a manner as to surround an outer periphery of the first region, as viewed in the first direction,
the third region on the substrate further includes a first conductor that is insulated from the first conductive pillar and provided in a wall shape extending in the first direction and surrounding the first region,
the passivation film overlaps the first conductor in the first direction, and
the first conductive pillar is provided outside the first conductor with respect to the first region.

18. The semiconductor device according to claim 15, wherein at least a part of the first conductive pillar is in direct contact with a resin covering the substrate.

19. The semiconductor device according to claim 15, wherein the first conductive pillar includes portions that are divided in the first direction and electrically insulated.

20. The semiconductor device according to claim 15, wherein the passivation film includes polyimide.
